(19) United States
(12) Patent Application Publication
(10) Pub. No.: US 2014/0217451 A1
(43) Pub. Date: Aug. 7, 2014

(54) MIXED LIGHT LED STRUCTURE

(71) Applicant: UNITY OPTO TECHNOLOGY CO., LTD., NEW TAIPEI CITY (TW)

(72) Inventor: CHING-HUEI WU, NEW TAIPEI CITY (TW)

(73) Assignee: UNITY OPTO TECHNOLOGY CO., LTD., NEW TAIPEI CITY (TW)

(21) Appl. No.: 14/247,360

(22) Filed: Apr. 8, 2014

Related U.S. Application Data
(62) Division of application No. 13/795,152, filed on Mar. 12, 2013.

(30) Foreign Application Priority Data
Jan. 22, 2013 (TW) 102201358

(51) Int. Cl. H01L 33/50

(52) U.S. Cl. CPC H01L 33/502; H01L 33/505
USPC 257/98

(57) ABSTRACT

Disclosed is a mixed light LED structure which is a solid-state phosphor plate manufactured by mixing phosphor and resin, and the solid-state phosphor plate is installed in a carrier and covered onto the top of a light emitting chip, and a specific ratio relation between the area of the solid-state phosphor plate and the area of the light emitting chip area or a specific ratio relation between the area of the solid-state phosphor plate and the area of a light emitting hole are used, and also the relation of limiting the distance between the solid-state phosphor plate and the light emitting chip is satisfied, so as to achieve a better mixed light effect and a longer service life of the mixed light LED structure.

### CROSS-REFERENCE TO RELATED APPLICATIONS

This application is a divisional patent application of U.S. application Ser. No. 13/795,152 filed on Mar. 12, 2013, currently pending, the entire contents of which are hereby incorporated by reference for which priority is claimed under 35 U.S.C. §120.

### BACKGROUND OF THE INVENTION

1. Field of the Invention

The present invention relates to a light emitting diode (LED) structure, and more particularly to a mixed light LED structure capable of simplifying the manufacturing process, providing a convenient assembling process, and lowering the cost effectively.

2. Description of the Related Art

Most conventional LEDs used for indicating an application of electronic products have the advantages of low power consumption, long life and no heat generation, so that the LEDs can be used extensively in the areas of large displays and illuminations. In addition, it is a key technical feature whether or not the LED can generate white light.

Since a general LED emits colored lights such as the lights of three primary colors and these color lights can be mixed to produce a white light, therefore red, green and blue light emitting chips are required. By exciting different currents, the color lights can be mixed to produce the white light. In general, a conventional white light LED has the red, blue and green light emitting chips encapsulated in a package. In addition, a controller chip is sealed in the package, and crystal wires are used for connecting leads of the three light emitting chips and the controller chip. The three light emitting chips are arranged separately from one another, and the area of emitting the white light is limited to the intersection of the lights emitted from the three chips, but the light emitted from the periphery of each chip and the intersection of two chips are the light of each chip and the mixed light of two chips instead of the white light. Furthermore, a controller chip is required additionally, and thus not only incurring a higher cost, but also requiring a more complicated manufacturing process.

In general, the conventional surface mount device (SMD) LED is packaged by the following two methods. One of the methods is to use a metal leadframe as a packaging substrate and mount the LED chip onto the leadframe, and the other method is to use a printed circuit board (PCB) as the packaging substrate and mount the LED chip onto the PCB by die bonding. During the packaging process, a phosphor is distributed around the LED chip. If the LED chip emits a light source in a blue color and excites the phosphor directly to produce a yellow light, the yellow light can be mixed with the blue light to produce the white light. The phosphor distributed directly around the LED chip facilitates the light mixing process and improves the light emitting uniformity of the LED to a certain extent. However, the temperature usually reaches 70˜80 degrees in an operation of the LED, and such high temperature reduces the efficiency of the phosphor and lowers the light emission efficiency and uniformity of the LED.

Therefore, it is a urgent and important subject for related manufacturers to develop a mixed light LED structure, wherein the solid-state phosphor plate is excited by color lights to produce a uniformly mixed light source without a color difference.

### SUMMARY OF THE INVENTION

In view of the problems of the prior art, it is a primary objective of the present invention to overcome the problems of the prior art by providing a mixed light LED structure with a uniform mixed light effect.

To achieve the aforementioned objective, the present invention provides a mixed light LED structure, having a solid-state phosphor plate formed by mixing a phosphor and a resin and installed in a carrier, and the carrier having a concave cup and a light emitting hole formed at the upper edge of the concave cup, and the concave cup having a light emitting chip installed at the bottom of the concave cup, and the solid-state phosphor plate being covered onto the top of the light emitting chip, characterized in that the solid-state phosphor plate has an area of X, and the light emitting hole has an area of Y, and the area of the solid-state phosphor plate and the area of the light emitting hole satisfy the relation of 85%*Y≦X; the solid-state phosphor plate and the light emitting chip have a distance L apart from each other, and the distance L satisfies the relation of 0≦L≦50 mm.

In a preferred embodiment, the light emitting chip is electrically coupled to two electrodes on the carrier by a bonding wire through a wire bonding method, and the solid-state phosphor plate is abutted against a wall edge of the concave cup and situated at a position higher than the height of the bonding wire.

In another preferred embodiment, the light emitting chip is coupled to two electrodes on the carrier by a flip chip method.

To achieve the aforementioned objective, the present invention further provides a mixed light LED structure, having a PCB and a solid-state phosphor plate formed by mixing a phosphor and a resin, and the PCB having at least two electrodes and a light emitting chip, and the two electrodes being electrically coupled to the light emitting chip, and a translucent resin being used for fixing and covering the solid-state phosphor plate onto the top of the light emitting chip, characterized in that the solid-state phosphor plate has an area of X, and the light emitting chip has an area of Z, and the area of the solid-state phosphor plate and the area of the light emitting chip satisfy the relation of Z≦X, and the light emitting chip is coupled to the two electrodes on the PCB by a flip chip method.

To achieve the aforementioned objective, the present invention further provides a mixed light LED structure, having a ceramic plate and a solid-state phosphor plate formed by mixing a phosphor and a resin, and the ceramic plate having at least two electrodes and a light emitting chip, and the two electrodes being electrically coupled to the light emitting chip, and a translucent resin being used for fixing and covering the solid-state phosphor plate onto the top of the light emitting chip, characterized in that the solid-state phosphor plate has an area of X, and the light emitting chip has an area of Z, and the area of the solid-state phosphor plate and the area of the light emitting chip satisfy the relation of Z≦X, and the light emitting chip is coupled to the two electrodes of the ceramic plate by a flip chip method.

Wherein, the resin of the solid-state phosphor plate is one selected from the collection of epoxy resin, polyphthalamide (PPA) and silica gel, and the phosphor of the solid-state phosphor plate has a general formula selected from the collection of (Ba, Sr, Ca)₂SiO₄:Eu²⁺, Y₃Al₅O₁₂:Ce³⁺(SrCa)AlSiN₃:Eu, (Ba, Sr, Ca)Ga₂S₄:Eu and Tb₃Al₅O₁₂:Ce³⁺.

The technical content of the present invention will become apparent with the detailed description of preferred embodiments and the illustration of related drawings as follows.

### BRIEF DESCRIPTION OF THE DRAWINGS

FIG. 1 is a first schematic view of a mixed light LED structure in accordance with a first preferred embodiment of the present invention;

FIG. 2 is a second schematic view of a mixed light LED structure in accordance with the first preferred embodiment of the present invention;

FIG. 3 is a first schematic view of a mixed light LED structure in accordance with a second preferred embodiment of the present invention;

FIG. 4 is a second schematic view of a mixed light LED structure in accordance with the second preferred embodiment of the present invention;

FIG. 5 is a first schematic view of a mixed light LED structure in accordance with a third preferred embodiment of the present invention; and

FIG. 6 is a second schematic view of a mixed light LED structure in accordance with the third preferred embodiment of the present invention.

### DETAILED DESCRIPTION OF THE PREFERRED EMBODIMENTS

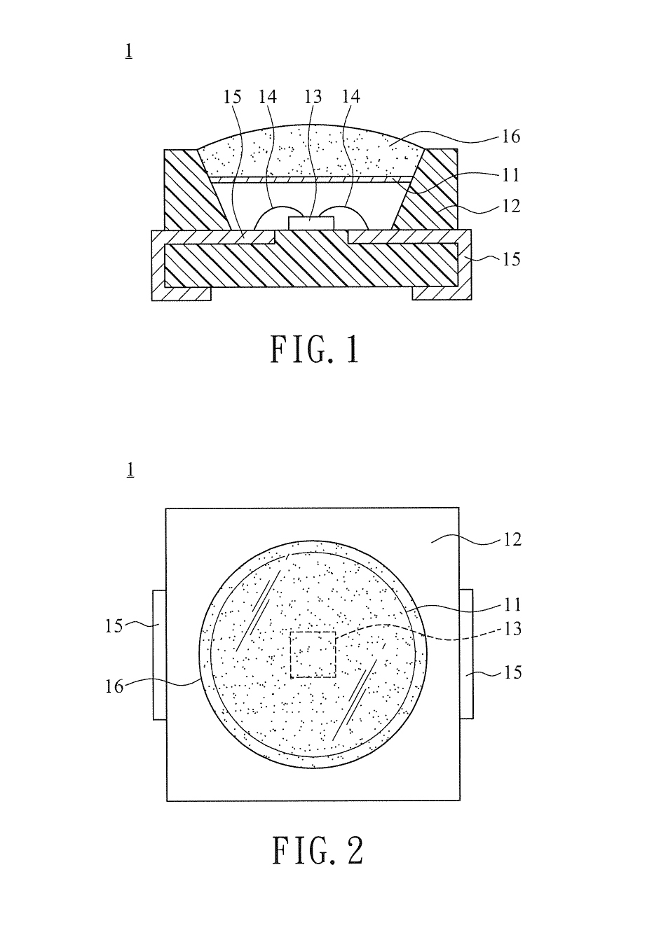

With reference to FIGS. 1 and 2 for a cross-sectional view and a top view of a mixed light LED structure in accordance with the first preferred embodiment of the present invention respectively, the mixed light LED structure 1 has a carrier 12, and the carrier 12 has a concave cup, a light emitting hole formed at an upper edge of the concave cup, and a light emitting chip 13 installed at the bottom of the concave cup, and a solid-state phosphor plate 11 is covered onto the top of the light emitting chip 13.

The solid-state phosphor plate 11 is formed by mixing a phosphor and a resin by injection molding or molding, wherein the resin is preferably epoxy resin, polyphthalamide (PPA) or silica gel, and the phosphor preferably has a general formula including but not limited to (Ba, Sr, Ca)₂SiO₄:Eu²⁺, Y₃Al₅O₁₂:Ce³⁺, (SrCa)AlSiN₃:Eu, (Ba, Sr, Ca)Ga₂S₄:Eu and Tb₃Al₅O₁₂:Ce³⁺.

When the light emitting chip 13 is electrically coupled to two electrodes 15 on the carrier 12 by a bonding wire 14 through a wire bonding method, the solid-state phosphor plate 11 abuts against a wall edge of the concave cup and situated at a position higher than the height of the bonding wire 14.

It is noteworthy that the solid-state phosphor plate 11 has an area equal to X, and the light emitting hole has an area equal to Y, and the area of the solid-state phosphor plate 11 and the area of the light emitting hole satisfy the relation of 85%*Y≦X in this preferred embodiment. In FIGS. 1 and 2, the solid-state phosphor plate 11 is installed in the light emitting hole. However, the area of the solid-state phosphor plate 11 and the area of the light emitting hole satisfy the relation of 85%*Y≦X, so that the solid-state phosphor plate 11 can be installed at the top or at the bottom of the light emitting hole. In other words, the solid-state phosphor plate 11 can be snapped into the concave cup or directly set on the concave cup. It is noteworthy that this preferred embodiment is provided for the purpose of illustration, but not intended for limiting the scope of the present invention.

To separate the light emitting chip 13 and the two bonding wires 14 from the outside, a translucent resin 16 is coated on the solid-state phosphor plate 11 or filled in the solid-state phosphor plate 11, and the translucent resin 16 can be epoxy resin, polyphthalamide (PPA) or silica gel, so that the translucent resin 16 can fix the solid-state phosphor plate 11 in the concave cup, and the solid-state phosphor plate 11 isolates the translucent resin 16 from covering the light emitting chip 13 to save the consumption of the translucent resin 16 effectively during the manufacture of the mixed light LED structure 1 of the present invention. Wherein, the translucent resin 16 is not limited to those described above. In the meantime, the solid-state phosphor plate 11 and the light emitting chip 13 have a distance L apart from each other, and the distance L satisfies the relation of 0≦L≦50 mm.

After the mixed light LED structure 1 of the present invention is connected to a power supply, the color light emitted by the light emitting chip 13 can pass through the solid-state phosphor plate 11 containing the phosphor with a uniform thickness, so that the solid-state phosphor plate 11 is excited by the color light to produce a uniform mixed light source without a color difference.

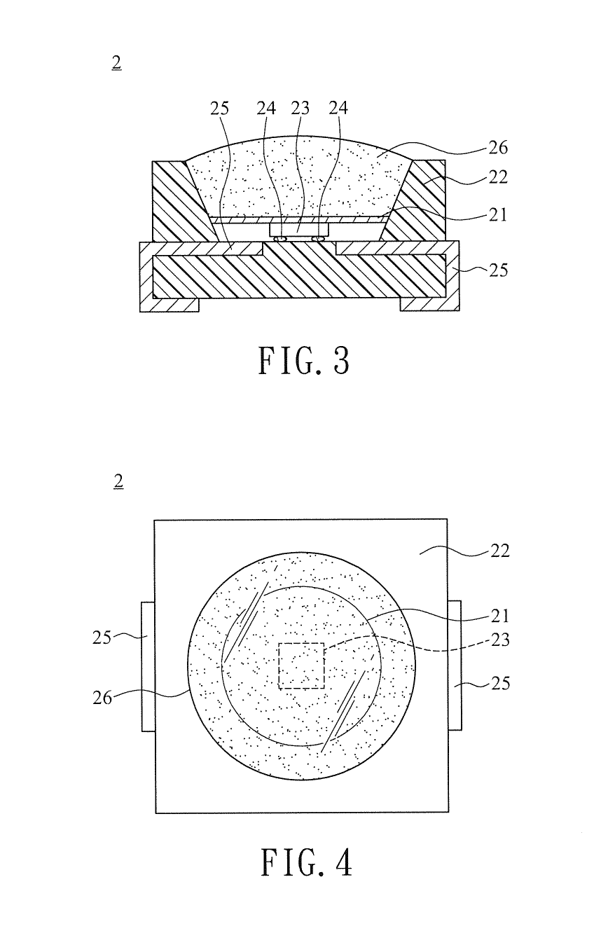

With reference to FIGS. 3 and 4 for a cross-sectional view and a top view of a mixed light LED structure in accordance with the second preferred embodiment of the present invention respectively, the mixed light LED structure 2 has a carrier 22, and the carrier 22 has a concave cup, a light emitting hole formed at an upper edge of the concave cup, and a light emitting chip 23 installed at the bottom of the concave cup. The difference between this preferred embodiment and the first preferred embodiment resides on that the light emitting chip 23 is coupled to two electrodes 25 on the carrier 22 is by a flip chip method instead, wherein a solder ball 24 or gold ball is coupled to pins 25 of different electrodes. In this preferred embodiment, the solder ball 24 is used as an example for the illustration, and the light emitting chip 23 is coupled to two pins 25 by connecting the solder ball 24 by a flip chip method, and a solid-state phosphor plate 21 is stacked onto the top of the light emitting chip 23. Since light emitting chip 23 is connected by the flip chip method, therefore the connection by the wire bonding method is no longer required, and the solid-state phosphor plate 21 can be stacked onto the light emitting chip 23 or installed at the top of the light emitting chip 23 directly.

It is noteworthy that the solid-state phosphor plate 21 has an area equal to X, and the light emitting hole has an area equal to Y. In this preferred embodiment, the area X of the solid-state phosphor plate 21 is equal to 85% of the area Y of the light emitting hole. In other words, the areas X and Y satisfy the relation of 85%*Y≦X, so that the solid-state phosphor plate 21 can be installed in the light emitting hole and flatly attached onto the top of the light emitting chip 23. However, the solid-state phosphor plate 21 and the light emitting hole have areas satisfy the relation of 85%*Y≦X. In other preferred embodiments, the solid-state phosphor plate 21 can be installed at different position such as the position above or below the light emitting hole. In other words, the solid-state phosphor plate 11 can be snapped into the concave cup or directly installed on the concave cup, but the invention is not limited to such arrangements only. In the meantime, the solid-state phosphor plate 21 and the light emitting chip 23 has a distance L apart from each other, and the distance L satisfies the relation of 0≦L≦50 mm, wherein the distance L of this preferred embodiment is equal to 0.

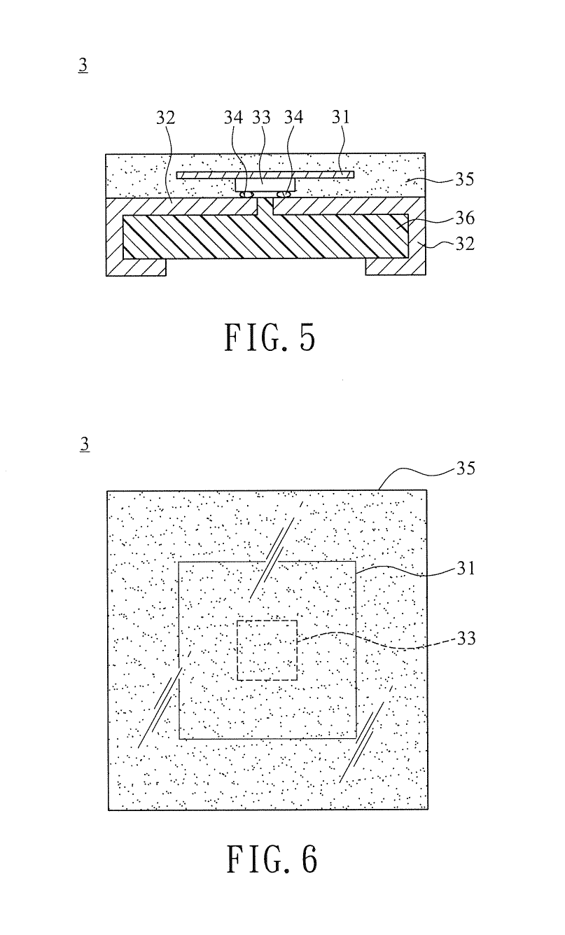

With reference to FIGS. 5 and 6 for a cross-sectional view and a top view of a mixed light LED structure in accordance with the third preferred embodiment of the present invention respectively, the mixed light LED structure 3 has a printed circuit board (PCB) 36 (or ceramic plate) and a solid-state phosphor plate 31 formed by mixing a phosphor and a resin, and the PCB 36 (or ceramic plate) has at least two electrodes 32 and a light emitting chip 33, and a light emitting chip 33 is connected to two electrodes 32 on the PCB 36 (or ceramic plate) by a solder ball 34 through a flip chip method, and then the solid-state phosphor plate 31 is covered onto the light emitting chip 33, and a translucent resin 35 is provided for fixing the solid-state phosphor plate 31 onto the top of the light emitting chip 33 to produce a mixed light LED structure 3.

Wherein, the resin of the solid-state phosphor plate 31 includes epoxy resin, polyphthalamide (PPA) or silica gel, and the phosphor of the solid-state phosphor plate 31 has a general formula of (Ba, Sr, Ca)₂SiO₄:Eu²⁺, Y₃Al₅O₁₂:Ce³⁺, (SrCa)AlSiN₃:Eu, (Ba, Sr, Ca)Ga₂S₄:Eu or Tb₃Al₅O₁₂:Ce³⁺.

In summation of the description above, the mixed light LED structure of the present invention has the following advantages:

1. The solid-state phosphor plate of the mixed light LED structure of the present invention is used to simplify the manufacturing process of the mixed light LED structure effectively, so as to facilitate the assembling process and lowering the cost.

2. The solid-state phosphor plate of the mixed light LED structure of the present invention is a plate having a dissolved substance with a uniform thickness, such that when the solid-state phosphor plate is installed at the top of the chip, the mixed light emitted from the mixed light LED structure can achieve a uniform light color effect.

3. The solid-state phosphor plate of the mixed light LED structure of the present invention separates the concave cup of the carrier into two parts by the installation of the solid-state phosphor plate. When the translucent resin is sealed, only the space above the thin film is sealed only, but the space below the thin film is not filled, so as to save the material consumption of the translucent resin.

What is claimed is:

1. A mixed light LED structure, having a printed circuit board (PCB) and a solid-state phosphor plate formed by mixing a phosphor and a resin, and the PCB having at least two electrodes and a light emitting chip, and the two electrodes being electrically coupled to the light emitting chip, and a translucent resin being used for fixing and covering the solid-state phosphor plate onto the top of the light emitting chip, characterized in that the solid-state phosphor plate has an area of X, and the light emitting chip has an area of Z, and the area of the solid-state phosphor plate and the area of the light emitting chip satisfy the relation of Z≦X, and the light emitting chip is coupled to the two electrodes on the PCB by a flip chip method.

2. The mixed light LED structure of claim 1, wherein the resin of the solid-state phosphor plate is one selected from the collection of epoxy resin, polyphthalamide (PPA) and silica gel.

3. The mixed light LED structure of claim 1, wherein the phosphor of the solid-state phosphor plate has a general formula selected from the collection of (Ba, Sr, Ca)₂SiO₄:Eu²⁺, Y₃Al₅O₁₂:Ce³⁺, (SrCa)AlSiN₃:Eu, (Ba, Sr, Ca)Ga₂S₄:Eu and Tb₃Al₅O₁₂:Ce³⁺.

4. A mixed light LED structure, having a ceramic plate and a solid-state phosphor plate formed by mixing a phosphor and a resin, and the ceramic plate having at least two electrodes and a light emitting chip, and the two electrodes being electrically coupled to the light emitting chip, and a translucent resin being used for fixing and covering the solid-state phosphor plate onto the top of the light emitting chip, characterized in that the solid-state phosphor plate has an area of X, and the light emitting chip has an area of Z, and the area of the solid-state phosphor plate and the area of the light emitting chip satisfy the relation of Z≦X, and the light emitting chip is coupled to the two electrodes of the ceramic plate by a flip chip method.

5. The mixed light LED structure of claim 4, wherein the resin of the solid-state phosphor plate is one selected from the collection of epoxy resin, polyphthalamide (PPA) and silica gel.

6. The mixed light LED structure of claim 4, wherein the phosphor of the solid-state phosphor plate has a general formula selected from the collection of (Ba, Sr, Ca)₂SiO₄:Eu²⁺, Y₃Al₅O₁₂:Ce³⁺, (SrCa)AlSiN₃:Eu, (Ba, Sr, Ca)Ga₂S₄:Eu and Tb₃Al₅O₁₂:Ce³⁺.
